(19) United States
(12) Patent Application Publication
(10) Pub. No.: US 2023/0352538 A1
(43) Pub. Date: Nov. 2, 2023

(54) APPLICATIONS OF TWO-DIMENSIONAL SILICON CARBIDE AS THE CHANNEL LAYER IN FIELD-EFFECT TRANSISTORS

(71) Applicant: UNM RAINFOREST INNOVATIONS, Albuquerque, NM (US)

(72) Inventor: Sakineh CHABI, Albuquerque, NM (US)

(21) Appl. No.: 18/307,173

(22) Filed: Apr. 26, 2023

Related U.S. Application Data
(60) Provisional application No. 63/337,239, filed on May 2, 2022.

(51) Int. Cl. H01L 29/16; H01L 29/06; H01L 29/786; H01L 29/775; H01L 33/34

(52) U.S. Cl. CPC H01L 29/1608; H01L 29/0673; H01L 29/78696; H01L 29/775; H01L 33/34

(57) ABSTRACT

A semiconductor device includes a substrate with at least one epitaxial layer disposed onto the substrate, a 2D silicon carbide layer disposed onto the at least one epitaxial layer. The device also includes a source region. The device also includes a drain region. The device also includes where the 2D silicon carbide layer provides a conducting path between the source region and the drain region. The semiconductor device may include where the 2D silicon carbide layer is a channel layer. The semiconductor device can be a transistor, such as a metal-oxide semiconductor field-effect transistor (MOSFET), or a light-emitting diode.

### REFERENCE TO RELATED APPLICATIONS (PROVISIONAL)

This application claims the benefit of U.S. Provisional Patent Application No. 63/337,239, filed on May 2, 2022, which is hereby incorporated by reference in its entirety.

### TECHNICAL FIELD

The present teachings relate generally to semiconductor devices and, more particularly, to semiconductor devices including silicon carbide as a channel layer in semiconductor devices.

### BACKGROUND

Silicon Carbide (SiC) powered devices, including metal-oxide-semiconductor field-effect transistors (MOSFET) are increasingly being used in high power, high voltage, and high temperature applications because SiC has a larger bandgap, and much better thermal conductivity as compared to silicon. The use of SiC MOSFETs in battery applications, such as electric vehicles (EVs) enables fast charging, since SiC can tolerate high voltage, high frequency operation when incorporated into semiconductor devices. Despite several advantages that SiC power devices have over silicon, they still have disadvantages. Current challenges with SiC MOSFETs include power loss due to the conduction loss, and material quality. These problems degrade the performance and reliability of the device, and increase the overall cost.

Modern optoelectronic and electronic technologies need to be lightweight, ultrafast and highly efficient (with minimum power loss). These characteristics cannot be achieved with conventional semiconducting materials such as silicon. Bulk silicon carbide (SiC), by contrast, has many exceptional physical properties, including a wide band gap, high breakdown field, high strength, and high temperature tolerance. It is widely used in high-temperature, high-frequency, and high-power electronics, and as a wide band gap semiconducting material, silicon carbide has an edge over silicon. In addition, SiC benefits from high chemical and thermal stability and it demonstrate an ability to resist radiation. These characteristics are critical for its application in extreme electronic environments. However, as a result of its quantum confinement, 2D SiC offers additional opportunities for applications compared to the corresponding bulk material. For instance, 2D SiC provides unusual physical properties, which are absent in other SiC configurations such as bulk SiC or one dimensional SiC. Therefore, there is a need for devices incorporating 2D silicon carbide (SiC) as nanosheets and other configurations.

### SUMMARY

The following presents a simplified summary in order to provide a basic understanding of some aspects of one or more embodiments of the present teachings. This summary is not an extensive overview, nor is it intended to identify key or critical elements of the present teachings, nor to delineate the scope of the disclosure. Rather, its primary purpose is merely to present one or more concepts in simplified form as a prelude to the detailed description presented later.

A semiconductor device is disclosed. The semiconductor device also includes a substrate with a 2D silicon carbide nanosheet layer disposed onto the substrate. The device also includes a source region. The device also includes a drain region. The device also includes where the 2D silicon carbide nanosheets layer provides a conducting path between the source region and the drain region. Implementations of the semiconductor device may include where the 2D silicon carbide layer is a channel layer. Both 2D silicon carbide (mono layer, few layer), and multi-layer silicon carbide can be used as channel layer. A thickness of the silicon carbide channel layer is from about 0.25 nm to about 25 nm. The 2D silicon carbide layer may include a single layer. The silicon carbide channel layer may include from about 1 to about 100 layers. The semiconductor device may include a planar structure. The semiconductor device may include a stacked design, and more than one gate layer. The semiconductor device can be a transistor. The semiconductor device can be a MOSFET. The semiconductor device can be a light-emitting diode. The light-emitting diode can be a blue light-emitting diode.

Another semiconductor device is disclosed. The semiconductor device includes a substrate, at least one epitaxial layer disposed onto the substrate, a channel layer may include 2D silicon carbide, disposed onto the at least one epitaxial layer. The device can include a source region in contact with the channel layer. The device also includes a drain region in contact with the channel layer. Implementations of the semiconductor device may include where a thickness of the 2D silicon carbide layer is from about 0.25 nm to about 25 nm. The silicon carbide nanosheets layer may include from about 1 to about 100 layers. The semiconductor device is a transistor. The semiconductor device is a MOSFET.

A semiconductor device is disclosed, including a substrate, a channel layer may include 2D silicon carbide, disposed onto the substrate. The device also includes a source region in contact with the channel layer. The device also includes a drain region in contact with the channel layer. The device also includes at least one insulating layer in contact with the channel layer. The device also includes at least one gate oxide layer in contact with the at least one insulating layer. The device also includes where the channel layer may include from about 1 to about 100 layers.

The features, functions, and advantages that have been discussed can be achieved independently in various implementations or can be combined in yet other implementations further details of which can be seen with reference to the following description.

### BRIEF DESCRIPTION OF THE DRAWINGS

The accompanying drawings, which are incorporated in and constitute a part of this specification, illustrate embodiments of the present teachings and together with the description, serve to explain the principles of the disclosure. In the figures:

FIG. 1A is an optical microscopy image of a 2D SiC nanosheet, in accordance with the present disclosure.

FIG. 1B is a high-resolution transmission electron microscopy (TEM) image of the 2D SiC nanosheet, in accordance with the present disclosure.

FIG. 2 is a scanning electron microscope (SEM) image of silicon carbide nanosheets on a silicon chip, in accordance with the present disclosure.

FIG. 3 is a schematic of a SiC MOSFET device, in which 2D SiC is being used as a channel layer, in accordance with the present disclosure.

FIG. 4 depicts a plot of a photoluminescence (PL) measurement using the 2D SiC nanosheets in a measurement, in accordance with the present disclosure.

It should be noted that some details of the figures have been simplified and are drawn to facilitate understanding of the present teachings rather than to maintain strict structural accuracy, detail, and scale.

### DETAILED DESCRIPTION

Reference will now be made in detail to exemplary embodiments of the present teachings, examples of which are illustrated in the accompanying drawings. Wherever possible, the same reference numbers will be used throughout the drawings to refer to the same, similar, or like parts.

SiC nanosheets devices have interesting properties such as atomic thickness, excellent crystal structure, and high environmental/thermal stability that give customers the ability to squeeze more power into more compact designs that weigh less and create less heat, thus, resulting in better power density. Due to their atomic thickness, SiC nanosheets channel materials are suited to push the scaling limits beyond those of silicon. Thus, improved efficiency, space and weight savings, and enhanced system reliability will be the encountered positive effects. The use of 2D SiC nanosheets in MOSFET will enable better carrier mobility, substrate flexibility, reduced short-channel effects, and lack of dangling bonds. These features all further contribute positively to the overall performance and efficiency of the device.

Owing to their atomic thickness, the use of SiC nanosheets (instead of bulk SiC) enables more packed devices, and scaling down the physical size of transistors.

Further, compared to bulk SiC which usually form a thick oxide layer (e.g. 200 nm SiO₂) readily, 2D SiC nanosheets show excellent stability towards oxidation, and this will positively affect their durability and performance. The thickness of grown SiC nanosheets in laboratory conditions ranges from 0.25 nm to 25 nm. In examples, layers can ranges from about 0.25 nm to about 100 nm, or from about 1 nm to about 50 nm, or from about 1 nm to about 50 nm. Additionally, bulk SiC suffers from poor crystalline structure, however 2D SiC has an ordered crystalline structure and this will positively affect materials reliability and performance. Thus, reduced thickness and structural flexibility, quantum confinement effects, improved crystallin structures and excellent environmental stability, and structural flexibility are expected to positively impact the power efficiency of the device. The use of SiC nanosheets in MOSFET introduces several degrees of freedom into device design, and both 2D SiC (monolayer, few layer), and stacked multilayer SiC can be used. The use of stacked SiC nanosheets as channel layer, enables multiple gates on the channel layer. In this case the channel layer are completely surrounded by the gate, and current leakage is reduced. Also, by shortening the channel length, the channel resistance can be reduced which will positively impact power efficiency.

The fabrication of hexagonal monolayer silicon carbide using hexagonal SiC particles as a precursor as described herein facilitates the isolation of monolayer SiC from bulk SiC in a liquid exfoliation process. The wet exfoliation process and associated methods enable the use of various SiC precursor materials, and may also be applicable to other materials to fabricate 2D materials based on other compositions. Liquid exfoliation processes as may also be combined with or complemented by other fabrication methods to create monolayer or 2D materials. Two-dimensional silicon carbide, or 2D-SiC, may alternatively be referred to as silicon carbide nanosheets, monolayer silicon carbide, monolayer SiC, few-layer silicon carbide, few-layer SiC, or siligraphene. Furthermore, other two-dimensional materials of the present disclosure may also be referred to as 2D, nanosheet, monolayer, or few-layer.

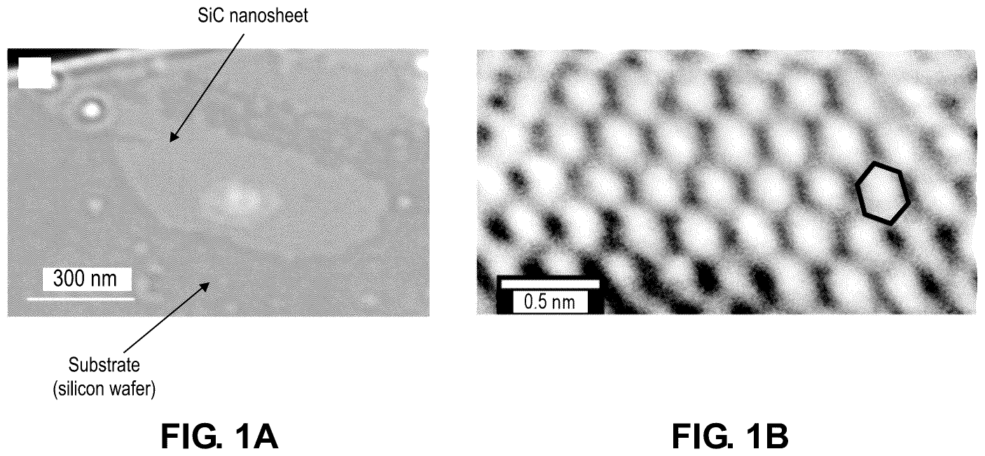

FIG. 1A is an optical microscopy image of a 2D SiC nanosheet, in accordance with the present disclosure. The optical microscopy image of the SiC nanosheet deposited on silicon wafer shows an atomically thin SiC nanosheet that is transparent. FIG. 1B is a high-resolution transmission electron microscopy (TEM) image of the 2D SiC nanosheet, in accordance with the present disclosure. The high resolution TEM images of the created 2D SiC shows no macroscopic defects such as stacking faults, or one dimensional, dislocation defects. Unlike bulk SiC that can be configured in 250 polytypes, monolayer SiC does not have any polytype. Instead, monolayer SiC has a perfect graphene-like hexagonal planar structure. This hexagonal shape is an indication of 100% crystallinity. The use of highly crystalline, atomically thin, i.e., less than 1 nm, 2D SiC nanosheets in MOSFETs can enable more compact devices, better carrier mobility with near-ballistic transport capability, substrate flexibility, reduced short-channel effects, and the lack of dangling bonds, all of which improve efficiency, reliability, and durability. This is in contrast to amorphous materials, which can oxidize easily, resulting in performance degradation of a device over time. Likewise, the reduction of thickness of a channel layer material reduces resistance of material, providing higher conductivity and increased control of the properties and design of devices. This and other proposed device of the present teachings can include a source region, a drain region and SiC nanosheet channels between the source and drain regions, as shown and described herein. It should be noted that SiC nanosheets (or 2D SiC), can be used with different designs/architectures of transistors. Furthermore, in addition to monolayer and few layer SiC, multilayer SiC nanosheets can also be used as channel layer in transistors.

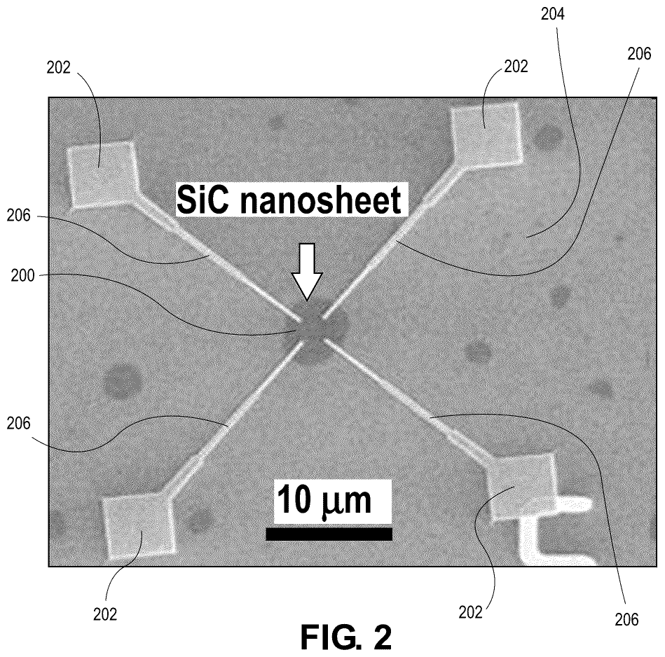

FIG. 2 is a scanning electron microscope (SEM) image of silicon carbide nanosheets on a silicon chip, in accordance with the present disclosure. The silicon carbide (SiC) nanosheet 200 is shown placed onto a silicon chip 204. Several metallic contacts 202 are connected to the silicon carbide (SiC) nanosheet 200 by wires 206. Replacing bulk SiC with 2D SiC has the following advantages: more packed devices, improved materials quality and reduced oxidation tendency, reduced short channel effects and improved mobility, all resulting in higher efficiency. Structurally, 2D SiC has been predicted to have a graphene-like honeycomb structure consisting of alternating Si and C atoms. In 2D or monolayer SiC, the carbon and silicon atoms will bond through sp2 hybrid orbitals to form a SiC sheet. Studies related to the stability of planar 2D SiC have confirmed that 2D SiC is energetically stable and has a 100% planar structure with inherent dynamic stability.

The compositional and structural properties of 2D SiC result in many attractive material properties. 2D SiC is a wide band gap semiconducting material with a number of potential applications including power electronics, optoelectronics, and spintronics. Unlike many other 2D materials such as silicene, or the 2D form of silicon, 2D SiC is environmentally stable and therefore useful for device fabrication. While Silicon carbide in bulk form may exist in as many as 250 polytypes, monolayer SiC does not have any polytype. Unlike bulk SiC which exhibits an indirect band gap, monolayer SiC has a direct band gap. This feature is important for optoelectronics and photonic applications. As atomic thick wide band gap semiconductor materials, the use of 2D SiC may enable faster, smaller, thinner electronic devices such as 2D SiC switches, nanosheet transistors, and the like. This direct band gap characteristic of 2D SiC may enable its use in several applications such as light emitting diodes, bioimaging, and the like. Depending on the number of layers, for example monolayer vs. bilayer SiC, or few-later SiC, the size of the band gap may vary. Compared to bulk SiC, 2D SiC also exhibits enhanced photoluminescence (PL) properties, non-linear optical properties, and notable mechanical properties. Two-dimensional SiC also has highly tunable electronic, optical, and mechanical properties. For example, optical and electronic properties of 2D SiC can be modified via several methods including chemical functionalization, introducing defects, applying mechanical strain, or combinations thereof. The aforementioned characteristics of 2D SiC lend its use in a variety of electronic devices or systems, including semiconductor devices, including, but not limited to transistors, MOSFETs, light-emitting diodes (LEDs), and the like.

In addition to the structural advantages of 2D SiC, the key properties of 2D SiₓC_{y} may be also determined by the Si/C stoichiometric ratio. As a result of different composition, or ratio of Si:C, 2D silicon carbide could be tailored to exhibit a broad range of electronic, optical, magnetic, and mechanical properties. Therefore, alloying carbon and silicon atoms in such a planar two-dimensional binary system offers a high level of capabilities, flexibilities, and functionalities, which are not attainable with the use of other closely related materials such as graphene or silicene. For example, depending on the composition 2D SixCy may behave as semiconductor, semimetal or topological instructor. As changing the composition (Si/C stoichiometry) will change the electronic band structure, and the band gap of the materials, resulting in different physical and chemical properties. The use of SixCy, instead of silicon, may also eliminate the need for doping in some applications, or it might improve mechanical properties of some compositions.

The electronic properties of 2D silicon carbide materials may be determined through their electronic band structure. The band gap behavior in 2D SiC is thought to be related to the electronegativity differences between silicon and carbon atoms, which would induce electron transfer from valance electrons of silicon to the nearest carbon, resulting in an emerging band gap. Theoretical calculations further predict that monolayer SiC is a direct bandgap semiconductor, which is in contrast with the indirect nature of the band gap in bulk SiC. Again, density functional theory calculations predict that monolayer SiC has a theoretical direct band gap of 2.55 eV. However, the calculated band gap is in the range of 3-4.8 eV when computed with GW quasiparticle corrections, GLLB-SC and other methods of approximation. The indirect-direct band gap transition characteristic in 2D SiC, is similar to the previously reported feature in other 2D materials such as 2D transition metal dichalcogenides (TMDs). This type of indirect-direct band gap transition may be attributed to a lack of any interlayer interactions in the TMDs monolayer. It may be noted that TMDs are van der Waals layered materials similar to graphite, and as such, they can easily be fabricated via mechanical exfoliation.

The electronic properties of 2D silicon carbide depend strongly on the number of layers, as well as the atomic ratio between carbon and silicon in SiₓC_{y}. The band structure of one to three layers of SiC is expected to experience significant deviation from that of bulk SiC. Alternate stacking sequences, for example, AB or ABC, may exhibit different band structures and thus, different properties. While it is also understood that monolayer SiC has a direct bandgap, multilayer SiC has been found to have an indirect bandgap, and therefore an indirect-direct band gap crossover is possible for up to three layered SiC. This band gap crossover, which reaches its limit in monolayer SiC, may be attributed to the reduced dimensionality and electronic confinement in the direction perpendicular to the c axis. The bandgap of few layer silicon carbide is expected to decrease as the number of layers increases. The latter can be attributed to the reduced dielectric screening in monolayer silicon carbide. In examples, electronic devices or other devices can have from 1 to about 100 layers of 2D SiC nanosheets, or from about 1 to about 50 layers of 2D SiC nanosheets, or from about 1 to about 10 layers of 2D SiC nanosheets.

The atomic ratio between carbon and silicon in 2D SiₓC_{y}, the effects of the edge structure (armchair or zigzag), structural defect levels, mechanical strain, and chemical doping may also influence the size of the bandgap and carrier mobility within 2D silicon carbide. Therefore, 2D silicon carbide materials, SiₓC_{y}, may benefit from highly tunable electronic properties. The band structure can be controlled by varying the Si:C composition, mechanical strain, and defects. This modifiability provides significant advantages as enables the use of 2D silicon carbide for a variety of applications.

Unlike bulk silicon carbide which is an indirect semiconductor with weak absorption and light emitting characteristics, 2D silicon carbide has very rich optical properties such as strong photoluminescence, and excitonic effects, as a result of its direct bandgap and quantum confinement effects. The optical absorption spectra of 2D silicon carbide are shown to vary depending on light polarization, number of the layers, and Si/C ratio in SiₓC_{y} structures. Light polarization due to the 2D SiC highly anisotropic optical properties.

Optical properties of 2D silicon carbide, such as absorption flux, exciton binding energy, optical conductivity, are also strongly affected by the atomic ratio between carbon and silicon. Depending on the compositions, SiₓC_{y} materials have different band structures and thus band gap. As discussed earlier, among SiₓC_{y} materials, 1:1 stoichiometry, i.e., SiC is expected to have the largest band gap. Theoretical studies have also reported that 2D silicon carbide has strong nonlinear optical properties. The nonlinear optical properties in silicon carbide materials, are also affected by the atomic ratio between C and Si. For example, it was reported that carbon-rich SiₓC_{y} materials, in bulk silicon carbide, have been shown to exhibit enhanced nonlinear refractive index as compared to more silicon-rich materials. This enhancement may be attributed to an increased saturable absorbance in carbon-rich materials as a result of delocalized p-electrons.

While bulk SiC is considered a candidate of interest for use in applications requiring materials having magnetism and spintronic properties, the expected properties of 2D SiC are also of interest. Monolayer planar SiC is known to be a non-magnetic semiconductor, and other forms of 2D SiC including defect-contained monolayer are known to exhibit magnetism behavior. Theoretical studies have found that the magnetic properties of 2D SiC can be tuned through doping, structural defects, mechanical strain, or combinations thereof. Suitable chemical dopants may include transition metals (TMs) or non-magnetic metals (NMMs) in order to tune magnetism behavior of 2D SiC. Structural defects may be introduced into 2D materials to engineer magnetic properties of 2D materials via the incorporation of vacancy defects. This approach has been used successfully in manipulating magnetism and spin fluctuations in graphene. In 2D SiC, three types of vacancy defects have been studied—single C or Si vacancy, Si+C divacancy, and Si—C anti-site defects in the monolayer. The aforementioned defects may be grown during the synthesis or surface defects may be introduced during fabrication to introduce magnetism or ferromagnetism behavior in monolayer SiC or other 2D materials as described herein.

It has been also reported that as the thickness of SiC nanosheets decreases, for example, from 9 to 3 nm, the saturation magnetization also increases. The observed magnetism may be related to defects with carbon dangling bond on the surface of nanosheets. Mechanical strain may also be used to tune magnetic properties of these materials, for example, with the introduction of compressive strain, in order to transform 2D SiC from a semi-conductor to a metal. Similar switchable magnetism has been observed in Mn-doped 2D SiC as well. This flexibility and modifiability of 2D SiC, acting as a ferromagnetic material at RT, is very useful for applications such as magnetic memories, magnetic storage and communications technology devices.

The mechanical properties of any material are determined by its in-plane and out of plane atomic bonding. Silicon carbide is one of the strongest known materials due to the strong covalent bonding of silicon and carbon. Similar to bulk SiC, 2D SiC is a brittle material and a sudden drop in the stress at high strain has been predicted. As compared to bulk SiC, which is a covalently bonded material along both c-axis and a-axis, monolayer silicon carbide is a single atom thick material, having no c-axis. As such, 2D SiC is expected to have different mechanical properties than bulk SiC. Theoretical studies indicate that 2D SiC may have anisotropic mechanical properties as well. Mechanical properties of 2D SiC, such as Young's modulus, in-plane stiffness, and toughness, can be strongly influenced by the structure of the edges, i.e., armchair or zigzag, and their orientations, as well as the atomic ratio between Si and C in SiₓC_{y}.

Due to the direct band gap properties of 2D SiC has great potential use in optoelectronic applications, such as light emitting diodes (LEDs), lasers, optical switches and solar cells. Monolayer or 2D silicon carbide, as described herein, also exhibits a tunable bandgap and a bright emission which is a useful property for engineering the optoelectronic response for the aforementioned applications. This flexibility in band gap alteration enables the fabrication of light emitting devices such as LEDs covering the entire visible spectrum. In addition to its tunable band gap, monolayer silicon carbide has a large exciton energy as a result of enhanced electron—hole interaction and reduced dielectric screening, which is also useful for optoelectronic applications. Large exciton binding energy leads to strong and long-lived excitons, thus making such materials indispensable for applications such as UV excitonic lasers. This property is desired for LEDs, photo markers and excitonic solar cells. Furthermore, 2D SiC can be useful in combination with other materials to enable a variety of highly efficient heterostructures for solar cell components, bioimaging and biosensor applications, cellular imaging, and transport applications.

As a one atom thick wide bandgap material, 2D SiC has potential for electronic devices, particularly in applications or devices benefitting from operation under high temperature, high-power, and high-frequency conditions. Since monolayer silicon carbide is only one atom thick, SiC electronics may exhibit (i) reduced ohmic resistance as a result of reduced thickness and (ii) smaller, lighter nanoelectronics devices. Another advantage is that unlike bulk SiC, which has more than 250 polytypes, monolayer SiC does not have any polytype. The elimination of stacking sequences makes the device fabrication process less complicated.

Depending on the composition, 2D SiₓC_{y} may behave as semiconductor, with approximate bandgap ranging from 0.0 to 4.0 eV, topological insulator or semimetal. This flexibility further expands the realm of 2D SiC, allowing it to be used for both high and low frequency electronic devices. 2D SiC materials can also be used along with other 2D materials to make a variety of 2D materials-based heterostructure devices by combining graphene or h-BN materials with 2D SiC when conductor or insulator (gate) are needed, respectively. Further still, compared to 2D materials other than graphene and h-BN, monolayer 2D SiC has higher in-plane stiffness and Young's Modulus rendering it beneficial for use in electromechanical devices. 2D SiC may also be used for quantum spintronics as well. Spintronic refers to spin-based electronics that rely on spin-controlled electronic properties. Silicon carbide materials offer such as spins associated with color centers with long coherence times as compared to diamond. 2D SiC, as compared to bulk SiC, offers an additional degree of freedom, allowing some control over the magnetic properties. As described earlier, 2D SiC has highly tunable magnetic properties enabling additional advantages for use in spintronic applications.

For the purposes of this disclosure, two-dimensional silicon carbide, or 2D-SiC, may alternatively be referred to as silicon carbide nanosheets, monolayer silicon carbide, monolayer SiC, few-layer silicon carbide, few-layer SiC, or siligraphene. Furthermore, other two-dimensional materials may also be referred to as 2D, nanosheet, monolayer, or few-layer.

Several types of semiconductor devices include channel layers, including transistors, MOSFETs, and LEDs. A channel layer is a thin layer of semiconductor material that provides a conducting path between a source region and a drain region of a device. Typically used semiconductor materials for channel layers include silicon and gallium arsenide. Silicon is an advantageous material used in channel layers due to its abundance, low cost, and electrical properties. Gallium arsenide possesses high electron mobility and high-frequency performance.

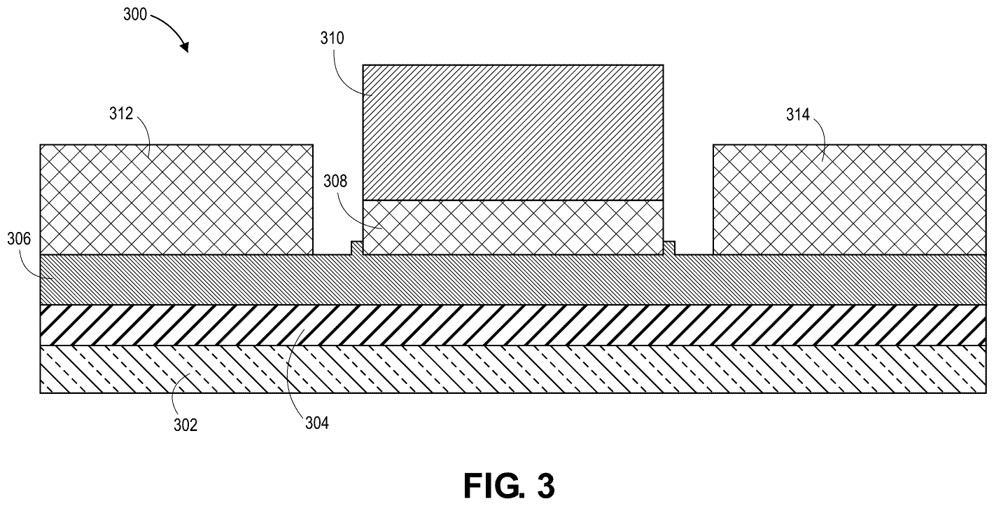

FIG. 3 is a schematic of a SiC MOSFET device, in which 2D SiC is being used as a channel layer, in accordance with the present disclosure. While a MOSFET device 300 is shown, the use of a 2D SiC may be applied to other electronic or semiconductor devices. The substrate layer 302 is the bottommost layer of the semiconductor device, and it provides the mechanical support for the device. Silicon is a common substrate material for semiconductor devices, but other exemplary materials like germanium and silicon carbide can be used. It should be noted that in certain examples, other materials or configurations can be utilized in semiconductor design. Next, an epitaxial layer 304, a thin layer of semiconductor material is grown on top of the substrate layer 302. The epitaxial layer 304 can be doped with impurities to modify the electrical properties of the epitaxial layer 304. Example materials for epitaxial layers include, but are not limited to silicon, gallium arsenide, and indium phosphide.

Upon the epitaxial layer 304 is a channel layer 306, a thin layer of semiconductor material that provides a conducting path between a source region 312 and a drain region 314 of the device 300. In the present disclosure, the channel layer 306 is comprised of one or more layers of 2D silicon carbide, or one or more SiC nanosheets. Typical materials for such a channel layer 306 can be or include silicon or gallium arsenide. A gate oxide layer 308 is a thin layer of insulating material, also referred to as an insulating layer, that is used to isolate a gate electrode 310 from the channel layer 306, which can, in examples, can include silicon dioxide. The gate electrode layer 310 is comprised of a thin layer of conducting material that is used to control the flow of current through the channel layer 306. Exemplary materials for gate electrode layers 310 include aluminum and polysilicon.

While not explicitly shown herein, channel layers of one or more layers of 2D silicon carbide, or one or more SiC nanosheets can be employed in other electronic devices or components, such as, but not limited to transistor devices, MOSFET devices, or LED devices. It is of note that SiC nanosheets (or 2D SiC), can be used with different designs or architectures of transistors. Further, in addition to monolayer and few layer SiC, multilayer SiC nanosheets can also be used as channel layer in transistors. For example, a transistor is a semiconductor device that is used to amplify or switch electronic signals. Base layers in a bipolar transistor can include a thin layer of semiconductor material, such as silicon or germanium, that is used to control the flow of current through the device. A collector layer includes a semiconductor material such as silicon to collect the electrons that flow through the device. An emitter layer is a layer of semiconductor material, for example, silicon, that is used to inject electrons into the device. Transistors can include channel layers comprised of one or more layers of 2D silicon carbide, or one or more SiC nanosheets. A MOSFET (Metal-Oxide-Semiconductor Field-Effect Transistor) is a type of transistor which can also include a channel layer or thin layer of semiconductor material that can create a conducting path between the source and drain regions of the MOSFET device. In accordance with the present teachings, a channel layer comprising one or more SiC nanosheets can be incorporated into a MOSFET type of transistor. An LED (Light Emitting Diode) emits light as a response to an electric. The structure of an LED device consists of several layers of semiconductor material, including, but not limited to a substrate layer, an n-type epitaxial layer, such as doped gallium nitride or aluminum-gallium nitride, or indium-gallium nitride. LEDs can include an active layer, thin layer that emits light when an electric current flows through it, such as indium gallium nitride, gallium arsenide, or gallium phosphide, and a p-type epitaxial layer, such as magnesium-doped gallium nitride, zinc oxide, or aluminum gallium nitride, and contact layer that provides a contact surface for one or more metal electrodes.

In addition to connecting the source and drain regions of a transistor, the channel layer can determine the electrical characteristics of a device, such as the current flow Channel layers are typically made from semiconducting materials, for example, silicon, germanium, or III-V compound semiconductors, and can be application dependent or material dependent, such as carrier mobility and bandgap associated with specific materials Channel layer materials are commonly doped to adjust or control the electrical properties. Materials having a large bandgap, such as silicon carbide, and in particular, nanosheets or 2D silicon carbide, can increase the breakdown voltage performance of a device and improve performance under high-temperature conditions. Other types of semiconductor devices that utilize channel layers include power devices, such as insulated-gate bipolar transistors (IGBTs) and Schottky diodes. Alternatively, SiC nanosheets can be used with other electronic devices such as silicon electronics. Thus, devices incorporating SiC nanosheets can include advantageous properties such as low atomic thickness, excellent crystal structure, and high environmental/thermal stability that give them the ability to insert more power into more compact designs that weigh less and create less heat, thus, resulting in improved power density. Due to their atomic thickness, SiC nanosheets channel materials can provide improved scaling limits beyond those of silicon. Thus, improved efficiency, space and weight savings, and enhanced system reliability can be additional positive effects.

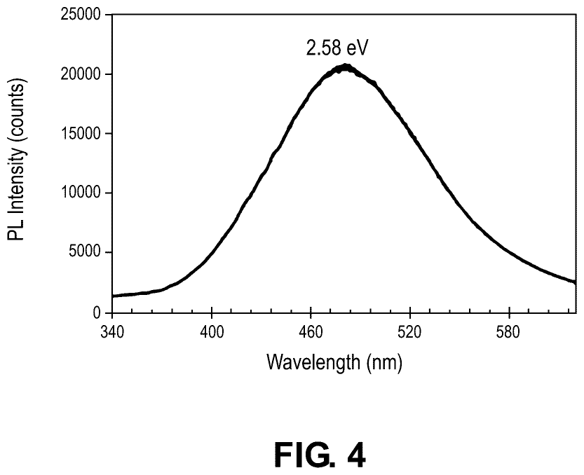

FIG. 4 depicts a plot of a photoluminescence (PL) measurement using the 2D SiC nanosheets in a measurement, in accordance with the present disclosure. FIG. 4 shows results from the photoluminescence (PL) measurement of the 2D SiC nanosheets. This result can be indicative of applications of SiC nanosheets in applications such as light emitting diodes (LEDs), and potentially Blue LEDs. The plot in FIG. 4 shows an emission peak at 2.58 eV, which is in the blue LED range. Photoluminescence (PL) measurements were performed at room temperature, using a UV micro-photoluminescence system and a sapphire substrate. PL samples were excited by a 269 nm excitation source.

Devices including SiC nanosheets devices can be designed in different structures, planar, including traditional, one-gate structure, or more advanced structures with multiple gates, more than one gate, and the like. Due to short channel effects, conventional planar structures cannot sustain further gate length scaling. However, stacked design, or devices including several gates, can be enabled with further scaling. Devices may further include one more n-drift layers, one or more p body layers, one or more n+ layers, depending on the design and functional requirements of such an electronic device incorporating a channel layer comprising SiC nanosheets.

While the present teachings have been illustrated with respect to one or more implementations, alterations and/or modifications may be made to the illustrated examples without departing from the spirit and scope of the appended claims. For example, it may be appreciated that while the process is described as a series of acts or events, the present teachings are not limited by the ordering of such acts or events. Some acts may occur in different orders and/or concurrently with other acts or events apart from those described herein. Also, not all process stages may be required to implement a methodology in accordance with one or more aspects or embodiments of the present teachings. It may be appreciated that structural objects and/or processing stages may be added, or existing structural objects and/or processing stages may be removed or modified. Further, one or more of the acts depicted herein may be carried out in one or more separate acts and/or phases. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items may be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. The terms “couple,” “coupled,” “connect,” “connection,” “connected,” “in connection with,” and “connecting” refer to “in direct connection with” or “in connection with via one or more intermediate elements or members.” Finally, the terms “exemplary” or “illustrative” indicate the description is used as an example, rather than implying that it is an ideal. Other embodiments of the present teachings may be apparent to those skilled in the art from consideration of the specification and practice of the disclosure herein. It is intended that the specification and examples be considered as exemplary only, with a true scope and spirit of the present teachings being indicated by the following claims.

What is claimed is:

1. A semiconductor device, comprising:
a substrate;
a 2D silicon carbide nanosheet layer disposed onto the substrate;
a source region; and
a drain region; and
wherein the 2D silicon carbide nanosheet layer provides a conducting path between the source region and the drain region.

2. The semiconductor device of claim 1, wherein the 2D silicon carbide nanosheet layer is a channel layer.

3. The semiconductor device of claim 1, wherein a thickness of the 2D silicon carbide nanosheet layer is from about 0.25 nm to about 25 nm.

4. The semiconductor device of claim 1, wherein the 2D silicon carbide nanosheet layer comprises a single layer.

5. The semiconductor device of claim 1, wherein the 2D silicon carbide nanosheet layer comprises from about 1 to about 5 layers.

6. The semiconductor device of claim 1, wherein the 2D silicon carbide nanosheet layer comprises from about 10 to about 100 layers.

7. The semiconductor device of claim 1, further comprising a planar structure.

8. The semiconductor device of claim 1, further comprising:
a stacked design; and
more than one gate layer.

9. The semiconductor device of claim 1, wherein the semiconductor device is a transistor.

10. The semiconductor device of claim 1, wherein the semiconductor device is a MOSFET.

11. The semiconductor device of claim 1, wherein the semiconductor device is a light-emitting diode.

12. The semiconductor device of claim 11, wherein the light-emitting diode is a blue light-emitting diode.

13. A semiconductor device, comprising:
a substrate;
at least one epitaxial layer disposed onto the substrate;
a channel layer comprising one or more 2D silicon carbide nanosheets, disposed onto the at least one epitaxial layer;
a source region in contact with the channel layer; and
a drain region in contact with the channel layer.

14. The semiconductor device of claim 13, wherein a thickness of the 2D silicon carbide nanosheet channel layer is from about 0.25 nm to about 25 nm.

15. The semiconductor device of claim 13, wherein the 2D silicon carbide nanosheet layer comprises from about 1 to about 100 layers.

16. The semiconductor device of claim 13, wherein the semiconductor device is a transistor.

17. The semiconductor device of claim 13, wherein the semiconductor device is a MOSFET.

18. The semiconductor device of claim 13, wherein the semiconductor device is a light-emitting diode.

19. The semiconductor device of claim 18, wherein the light-emitting diode is a blue light-emitting diode.

20. A semiconductor device, comprising:
a substrate;
a channel layer comprising 2D silicon carbide nanosheets, disposed onto the substrate;
a source region in contact with the channel layer;
a drain region in contact with the channel layer;
at least one insulating layer in contact with the channel layer; and
at least one gate oxide layer in contact with the at least one insulating layer; and
wherein the channel layer comprises from about 1 to about 100 layers.
